(19) United States
(12) Patent Application Publication
(10) Pub. No.: US 2003/0095000 A1
(43) Pub. Date: May 22, 2003

(54) Apparatus with ultra high output power class D audio amplifier

(75) Inventors: Robert D. Ramage, Groveland, MA (US); Tak Ping Tsui, Malden, MA (US)

Correspondence Address: MAINE & ASMUS, 100 MAIN STREET, P O BOX 3445, NASHUA, NH, 03061-3445, US

(73) Assignee: ACOUSTIC TECHNOLOGY, INC.

(21) Appl. No.: 10/237,518

(22) Filed: Sep. 9, 2002

Related U.S. Application Data
(63) Continuation-in-part of application No. 10/158,434, filed on May 29, 2002.
(60) Provisional application No. 60/333,232, filed on Nov. 16, 2001.
(60) Provisional application No. 60/332,609, filed on Nov. 16, 2001.

(51) Int. Cl. H03F 3/38; H03F 3/217

(52) U.S. Cl. 330/10; 330/251

(57) ABSTRACT

An apparatus and electrical circuit utilizing a high power Class “D” type amplifier for delivering an audio signal to a acoustic transducer system. A PWM modulator, the output of which is inhibited during power fluctuations or in absence of an audio input, converts a suitably conditioned audio input signal into low power, high frequency positive and negative components 180 degrees out of phase. A PWM signal power amplifier stage and low pass filters amplify the signal components, remove the higher PWM switching carrier frequency and pass the results to a power audio transformer impedance matched to the output acoustic transducers. Feedback signals are taken from the power stage before the low pass filters, suitably conditioned and combined as negative feedback with the input analog audio signal to minimize output distortion and maintain correct audio output voltage with changing load impedance and power supply voltages.

### CROSS REFERENCE TO RELATED APPLICATIONS

This application claims priority under 35 U.S.C. 120 from a U.S. Provisional Patent Applications serial No. 60/332,609 filed on Nov. 16, 2001, serial No. 60/333,232, filed Nov. 16, 2001, and serial No. 10/158434, filed May 29, 2002, which are incorporated herein by reference for all purposes.

### TECHNICAL FIELD OF THE INVENTION

This invention relates generally to the field of audio amplification using switching techniques, and more particularly to an apparatus consisting of an ultra high output power class D type audio amplifier.

### BACKGROUND OF THE INVENTION

Of the four basic classes of audio amplifiers, only the class D has high efficiency independent of the input audio waveform and amplitude. A class A audio amplifier has the worst efficiency typical between 20-30% and its high standby or quiescent current flowing in its output power stage makes it a poor choice for battery powered devices or power applications over 15 watts. Both class AB and B audio amplifiers can have power efficiencies approaching 80%, but the efficiency is highly dependent on the input audio signal waveform and amplitude. While for most audio applications the class AB audio amplifier is a reasonable choice, when sustained full RMS output power of over 100 watts RMS is required, the heatsink and thus its physical size becomes quite large. Often when sustained full RMS output power is required and high distortion is acceptable, a saturated square wave drive technique is used. Using this type of waveform as the audio input signal can result in class AB amplifier efficiencies of over 80%, however the resultant rail to rail output square wave signal when applied to the acoustical transducer(s) causes overheating, poor transducer efficiency, increased mechanical stress and premature failures of the acoustical transducers.

The class D amplifier is a recent development largely brought about from advances in the switching the power supply and switching servo amplifier fields. When sustained full output power is desired, a class D amplifier with output efficiencies of over 80% independent of the drive signal shape or amplitude would be the amplifier of choice. Presently there are many commercial products available using class D principles, however since their target market is usually home entertainment, where low average power voice and music is being amplified, they are designed only for peak output power of usually 100 watts or less. Their high efficiency and reasonable distortion makes them ideal for this application and especially for battery power devices. In the home entertainment markets, wide audio bandwidth and simplicity are very important, therefore the class D amplifiers which target this market are designed to couple directly to the output speakers without using an output transformer.

U.S. Pat. No. 4,249,136 issued Feb. 3, 1981, U.S. Pat. No. 4,504,793 issued Mar. 12, 1985, U.S. Pat. No. 6,297,692 issued Oct. 2, 2001, and U.S. Pat. No. 6,300,825 issued Oct. 9, 2001, all illustrate a half bridge type of output power stage configuration and all show a direct connection to the output speaker after the low pass filter. In addition, these patents show different methods of providing negative feedback for stabilizing the circuit and reducing distortion. U.S. Pat. No. 4,968,938 issued Nov. 6, 1990, U.S. Pat. No. 6,262,632 issued Jul. 17, 2001 and U.S. Pat. No. 6,078,214 issued Jun. 20, 2000, illustrate the use of a full bridge output drive stage but still show a direct connection to the output load or speaker after the low pass filters. These three patents describe different circuit configurations to reduce the output filter inductance or in the case of the last two patents to eliminate the output filter inductance completely. U.S. Pat. No. 5,200,711 issued Apr. 6, 1993, illustrates a hybrid circuit configuration using a standard class AB analog amplifier with a speaker directly connected to the output of the class AB analog amplifier and a means for dynamically adjusting the positive and negative voltages applied to the class AB analog output stage based on the input audio voltage swing using switching techniques.

U.S. Pat. No. 5,986,498 ('498) issued Nov. 16, 1999, shows a switching transformer used to recombine the negative and positive halves of the modulated pulse width signal in combination with steering diodes, a zero crossing detector circuit and steering MOSFET switches (References 60 and 54 of FIG. 1). The intent of the output steering MOSFET switches is evident, but the circuit is less clear. In the '498, the PWM signal is passed through the output switching transformer, which is used to recombine the positive and negative signals in association with the output switching devices. This switching transformer is also used to match the speaker output impedance. The output low pass filter, used to remove the PWM carrier frequency, is shown between the switching transformer and the speaker. However, there are no provisions, discussed or illustrated to prevent core saturation of the output-switching transformer. If the pulse width modulator (PWM) is allowed to vary from 0 to 100% in respond to the input audio amplitude variations, the PWM can take on or become the audio input frequency instead of the much higher PWM carrier frequency.

To illustrate this in a worst case situation, imagine a 100 hertz square wave signal of sufficient amplitude that it causes a PWM output of 100%. The resulting output frequency is now no longer the much higher PWM carrier frequency but the 100-hertz square wave audio signal. This 100-hertz signal will quickly saturate an output transformer that is designed for a much high PWM carrier frequency. Using the standard formula for determining the number of turns on a transformers primary using a switched waveform: ((E_{dc})10+8)/4f(Aₑ)(Bₘₐₓ), where E_{dc} is the maximum voltage expected to be applied on the primary, f is the lowest expected frequency, Aₑ is the minimal core area and Bₘₐₓ is the maximum flux swing with (some margin of safety) before core saturation occurs. As an example, let E_{dc}=50 V_{DC}, f=500 KHz, Aₑ=0.2 and Bmax=1K (with a core saturation value of 8K), then the minimum required number of primary turns is 12.5 or rounding up, the number of primary turns becomes 13 turns. If this transform was constructed and instead of a frequency of 500 KHz applied to its primary, a frequency of 100 hertz was applied, the core swing or Bₘ would be about 4,800,000 verses the maximum specification of 8000 or about 600 times the allowable flux swing. The results would be extremely high currents flowing in the transformer primary and probably destruction of the output transformer drivers depending on their protection method.

As previously noted, when using a transformer in the output stage of a class D or switching style audio amplifier, care must be taken to prevent this output transformer from core saturation. Limiting the lowest input frequency allowed and limiting the input voltage swing so that the PWM output cannot approach 100% duty cycle can help, but the resulting switching output transformer would still require a larger core and larger number of primary turns since some portion of the lower frequency audio would still be present during full voltage excursions. The resulting increase primary inductance would limit the output power and cause high reverse voltage spikes or current that could damage the switching transformers driving devices. A far better approach as described in this invention is to place the low pass filter before the output transformer, the resultant audio signals from the low pass filter can then drive an audio output transformer directly, that is suitably constructed to handle the required output power, isolation requirements, perform the necessary impedance matching and handle the lowest audio frequency allowed.

### SUMMARY OF THE INVENTION

It is an object of the invention to provide a single ultra high power class D type audio amplifier that can output in excess of 2000 watts RMS continuously in a compact package.

Another object of the invention is to provide an ultra high power class D type audio amplifier that can effectively be powered from batteries and a single supply voltage.

Yet another object of the invention is to have the output power efficiency of such an ultra high power class D audio amplifier be greater than 80% independent of input waveform shape or amplitude.

Still yet another object is the use of sine wave drive versus saturated square wave drive for continuous tone outputs resulting in less stress, lower heating, longer life and higher efficiency of the output acoustical transducers when using such an ultra high power class D audio amplifier in siren applications.

An additional object of the invention is to have no popping or erroneous output signal applied to the acoustic transducer(s) during turn on or turn off of the power to such an ultra high power class D audio amplifier, thereby reducing failures of the output acoustical transducers.

A further object of the invention is to have no quiescent or standby current flowing when no audio input signal is present in the ultra high power class D amplifier.

Another further object of the invention is to have no warm up or stabilizing period required after the amplifier power is first applied in such an ultra high power class D audio amplifier.

A still further object of the invention is to have the high efficiency of this ultra high power switching mode or class D audio amplifier permit use of a smaller DC power source than would be necessary using a Class “AB” or “B” amplifiers of equivalent output power.

Another additional object of the invention is to provide a ultra high power class D audio amplifier that is very easy to manufacture since there are no output bias adjustments necessary and a small heatsink is required.

Still yet another additional object of the invention is to have very low heat and low electrical stresses on electrical components that result in ultra high power class D audio amplifiers that have very high reliability.

To these ends, there is disclosed a circuit or apparatus with an ultra high output power class D amplifier, having a means for converting a suitable conditioned audio input signal into two low power PWM equivalent output signals that accurately represent the positive and negative parts of the audio input as PWM signals and are 180 degrees out of phase with each other. The PWM carrier frequency is set much higher than the maximum expected audio input signal frequency. The means of power amplifying the two low power PWM output signals uses power-handling devices such as power MOSFETs. The low power PWM output signals may use a pre-driver to more rapidly drive the input capacitance of the MOSFETS, especially when multiple MOSFETS are connected in parallel to increase output power.

The apparatus may have a means of low pass filtering the power outputs of the power devices to remove the high frequency component of the PWM signal and reconstruct the positive and negative part of the audio input as two separate 180 degree out of phase audio signals. The low pass filters are connected ahead of the audio output power transformer to overcome transformer core saturation problems associated with using PWM modulation that can vary from 0 to 100% duty cycle for audio reproduction. The low pass filters remove the high frequency PWM component, and pass the power amplified audio component. The low pass filters may be configured to provide Power Factor Correction with passive or active circuitry to further increase overall efficiency of the apparatus.

There may be feedback signals taken from between the power amplifiers and the low pass power output filters and suitably conditioned to remove the high frequency PWM component, and then via a feedback loop circuit combined with the input signal to provide negative feedback thereby minimizing output distortion, controlling output amplitude, and maintaining correct amplitude with varying output impedance and supply voltage.

An audio power output transformer may be used to overcome core saturation problems associated with using PWM modulation that can have a 0% to 100% on time per audio cycle. The transformer may be used to combine the positive and negative excursions of the audio signals together to reproduce an amplified signal that accurately represents the input audio signal. The audio power transformer may be used to match the output impedance of the acoustic transducer(s), configured to provide isolation between input and output when isolation is required, or be configured as an autotransformer for non-isolated requirements.

The drawings constitute a part of this specification and include exemplary embodiments to the invention, which may be embodied in various forms. It is to be understood that in some instances various aspects of the invention may be shown exaggerated or enlarged to facilitate an understanding of the invention.

Other objects and advantages of the present invention will become apparent from the following descriptions, taken in connection with the accompanying drawings, wherein, by way of illustration and example, an embodiment of the present invention is disclosed.

### BRIEF DESCRIPTION OF THE DRAWINGS

FIG. 1 is a simplified block diagram/schematic of a preferred embodiment of the invention.

### DESCRIPTION OF THE PREFERRED EMBODIMENT

A detailed description of the preferred embodiment is provided herein. It is to be understood, however, that the present invention may be embodied in various forms. Therefore, specific details of the preferred embodiments are not to be interpreted as limiting, but rather as a basis for the claims and as a representative basis for teaching one skilled in the art to employ the present invention in virtually any appropriately detailed system, circuit, structure or manner.

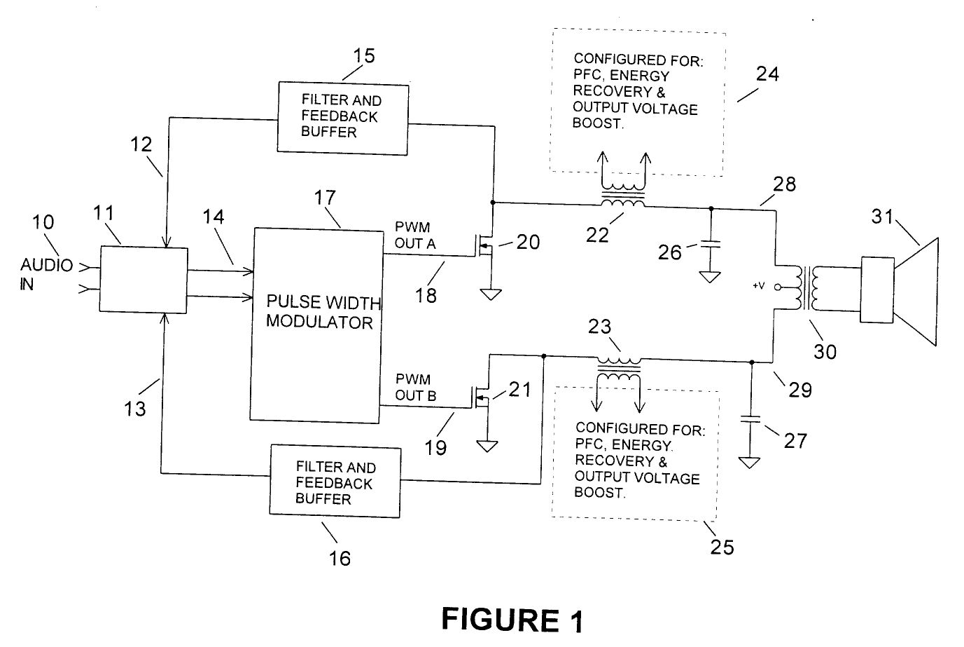

Referring to FIG. 1, there is illustrated a preferred embodiment of the invention incorporating an ultra high power class D audio amplifier circuit. An audio input signal 10 is connectible to signal conditioner 11 which applies a low frequency cutoff and voltage range limit to the signal. The conditioned audio signal 14 is from there applied to pulsewidth modulator 17, which converts the audio signal into two low power PWM (pulse wave modulated) equivalent signal components 18 and 19 that accurately represent the positive and negative parts of the audio input signal as two separate PWM signals that are 180 degrees out of phase with each other.

The two PWM signal components 18 and 19 are formed in modulator 17 using analog techniques in the preferred embodiment. Modulator 17 is designed to output a PWM signal only when a conditioned audio signal 14 is present at the input. Modulator 17 is further constrained by design to prevent erroneous output PWM signals at the time that power is applied or removed, thereby preventing damage to the output acoustic transducer(s) 30. The generation of PWM output signals using either analog or digital techniques in a PWM modulator is well understood in the art. The PWM carrier frequency is set at least 10 times the frequency of the maximum expected audio input frequency, thereby reducing the output filter requirements and voltage losses. Lower multiples are within the scope of the invention, so long as filtering is effective and voltage losses are tolerable.

The low power PWM signals 18 and 19 are connected to and power amplified by MOSFETs 20 and 21 respectively. Other power switching devices may be used to perform the power amplification of the PWM signals; power MOSFETs being the preferred devices. Also, when paralleling multiple MOSFETs to obtain higher output power levels, a suitable MOSFET pre-driver may be used to rapidly charge and discharge the MOSFET gates capacitance thus minimizing switching losses.

Low pass filters 22, 26 and 23, 27, effectively remove the high frequency PWM carrier component of the amplified PWM signals 18 and 19 and effectively reconstruct the positive and negative parts of the power amplified audio signal as two separate 180 degree out of phase audio signals 28 and 29. For very high output power levels, filters 22 and 23 may serve two purposes: the primary purpose being the inductive part of the output low pass filter and the second purpose being the transformer as part of either an active or passive Power Factor Correction (PFC) circuitry as indicated by PFC modules 24 and 25 and known in the art. For lower output power levels, PFC modules 24 and 25 may be omitted. If omitted, a correctly sized inductor for the desired output power and filtering action may replace filters 22 and 23.

The power amplified audio signals 28 and 29 are 180 degrees out of phase with each other. Signals 28 and 29 are recombined using audio output power transformer 30, arranged in a push pull configuration. The use of an audio output transformer designed to handle the lowest frequency audio signal allowed into the amplifier prevents the audio output transformer's core from saturating as the PWM signal approaches 100% duty cycle. The push pull power output driver configuration was chosen for its simplicity, single supply requirement and includes several protection schemes that are not shown but are easily implement by those skilled in the arts. Other power output drive configurations could be used to obtain the same high power output results, such as half bridge or full bridge circuit configurations. The audio power output transformer may be configured to provide either an isolated output as shown, or a non-isolated output. Also, multiple secondary outputs may be incorporated into transformer 30 to match various acoustical transducer impedance requirements. Audio power transformer 30 output is connected to acoustic transducer 31. The acoustic transducer may consist of multiple acoustical transducers sized to handle the desired output power.

Two feedback signals are taken from power MOSFETs 20 and 21 as drain outputs and are connected to filter and feedback buffers 15 and 16 respectively, removing the high frequency PWM carrier and reconstructing an amplified audio signal 12 and 13 that represent the audio input signal 10 as two 180 degrees out of phase signals. These two feedback signals 12 and 13 are then combined with input signal 10 in signal conditioner 11, as negative feedback that minimizes output distortion, controls output amplitude and maintains correct output amplitude with varying output impedance and power supply voltage variations.

Other and various embodiments are within the scope of the invention and claims that follow. For example, there is a circuit for delivering an audio signal to an acoustic transducer system, consisting of the following components. There is a signal conditioner for applying a low frequency cutoff and a desired output voltage range to the audio signal, a pulse width modulator connected to the output of the signal conditioner for converting the audio signal into positive and negative PWM signal components 180 degrees out of phase and having a PWM switching carrier frequency higher than the highest desired audio frequency of the audio signal. There are a pair of power amplifier circuits for amplifying the respective two PWM signal components. There is a negative feedback loop or circuit off the output of each of the power amplifiers back to the signal conditioner for minimizing output distortion and maintaining correct audio signal output voltage with changing load impedance and power supply voltages.

There is a low pass filter after each power amplifier for removing the PWM switching carrier frequency from the PWM signal components thereby converting the PWM signal components into high powered audio signal components. There is a power audio transformer for receiving and combining the audio signal components into a high power, output audio signal. The transformer is connected and impedance matched to the output acoustic transducer system, whereby the audio signal is emitted.

The feedback loops may have a filter and feedback buffer for removing the PWM switching carrier frequency. The power audio transformer may have a push pull configuration. The PWM switching carrier frequency may be 5 or 10 times the highest desired audio frequency to facilitate filtering. The low pass filters may include a power factor correction module or circuit.

The power amplifiers may use MOSFET devices, and may further include pre-driver MOSFET devices as described above. Other similar or equivalent amplifier circuits may be used.

As another example, there is an apparatus for delivering an audio signal to an acoustic transducer system, similarly configured with a signal conditioner for applying a low frequency cutoff and a desired output voltage range to the audio signal, a pulse width modulator connected to the output of the signal conditioner for converting the audio signal into positive and negative PWM signal components 180 degrees out of phase and having a PWM switching carrier frequency at least 5 or 10 times higher than the highest desired audio frequency of the audio signal, and power amplifiers for amplifying respective PWM signal components.

There is a negative feedback loop or circuit off the output of each said power amplifier back to said signal conditioner for minimizing output audio signal distortion and maintaining the correct audio output voltage range with changing system load impedance and power supply voltage.

There are low pass filters after each power amplifier for removing the PWM switching carrier frequency from the PWM signal components so as to convert the PWM signal components into audio signal components. A power audio transformer receives and combines the audio signal components into a high power output audio signal. The transformer is connected and impedance matched to the output acoustic transducer system.

The feedback loops may have a filter and feedback buffer circuit for adjusting phase and removing the PWM switching carrier frequency. The power amplifier circuits may employ MOSFET devices, and may further utilize pre-driver MOSFET devices as described above. The power audio transformer may have a push pull, half bridge, full bridge, or other functionally equivalent configuration. Each low pass filter may further include a power factor correction module or circuitry, whether active or passive. The output acoustic transducer system may use multiple audio speakers, and the output audio signal may have up to or greater than a continuous 2000 watts RMS power level.

The apparatus may be powered with a single supply voltage as is conveniently done with batteries and battery charging systems. The PWM modulator may be configured so as to be enabled for output only when an audio signal is present at its input. And the PWM modulator may be further configured so as to be disabled for output during power fluctuations and switching events in order to avoid impacting the quality of the output signal.

Other and numerous equivalent combinations of the elements and components and equivalent parts and circuits will be readily apparent to those skilled in the art upon being enlightened by this disclosure, all within the scope and spirit of the appended claims.

What is claimed is:

1. A circuit for delivering an audio signal to an acoustic transducer system, comprising
a signal conditioner for applying a low frequency cutoff and a desired output voltage range to said audio signal,
a pulse width modulator connected to the output of said signal conditioner for converting said audio signal into positive and negative PWM signal components 180 degrees out of phase and having a PWM switching carrier frequency higher than the highest desired audio frequency of said audio signal,
power amplifiers for amplifying respective said PWM signal components,
a negative feedback loop off the output of each said power amplifier to said signal conditioner for minimizing output distortion and maintaining correct output voltage with changing load impedance and power supply voltages,
a low pass filter after each said power amplifier for removing said PWM switching carrier frequency from said PWM signal components thereby converting the PWM signal components into audio signal components,
a power audio transformer for receiving and combining said audio signal components into an output audio signal, said transformer being connected and impedance matched to said output acoustic transducer system.

2. A circuit for delivering an audio signal according to claim 1, said feedback loops comprising a filter and feedback buffer for removing said PWM switching carrier frequency.

3. A circuit for delivering an audio signal according to claim 1, said power audio transformer having a push pull configuration.

4. A circuit for delivering an audio signal according to claim 1, said PWM switching carrier frequency being at least 10 times said highest desired audio frequency.

5. A circuit for delivering an audio signal according to claim 1, each said low pass filter further comprising a power factor correction module.

6. A circuit for delivering an audio signal according to claim 1, said power amplifiers comprising MOSFET devices.

7. A circuit for delivering an audio signal according to claim 6, said power amplifiers further comprising pre-driver MOSFET devices.

8. An apparatus for delivering an audio signal to an acoustic transducer system, comprising
a signal conditioner for applying a low frequency cutoff and a desired output voltage range to said audio signal,
a pulse width modulator connected to the output of said signal conditioner for converting said audio signal into positive and negative PWM signal components 180 degrees out of phase and having a PWM switching carrier frequency at least 10 times higher than the highest desired audio frequency of said audio signal,
power amplifiers for amplifying respective said PWM signal components,
a negative feedback loop off the output of each said power amplifier to said signal conditioner for minimizing output distortion and maintaining correct output voltage with changing load impedance and power supply voltages,
a low pass filter after each said power amplifier for removing said PWM switching carrier frequency from said PWM signal components thereby converting the PWM signal components into audio signal components,
a power audio transformer for receiving and combining said audio signal components into an output audio signal, said transformer being connected and impedance matched to said output acoustic transducer system, said feedback loops comprising a filter and feedback buffer for removing said PWM switching carrier frequency, said power amplifiers comprising MOSFET devices.

9. An apparatus for delivering an audio signal according to claim 8, said power amplifiers further comprising pre-driver MOSFET devices.

10. An apparatus for delivering an audio signal according to claim 8, said power audio transformer having a push pull configuration.

11. An apparatus for delivering an audio signal according to claim 8, said power audio transformer having a half bridge configuration.

12. An apparatus for delivering an audio signal according to claim 8, said power audio transformer having a full bridge configuration.

13. An apparatus for delivering an audio signal according to claim 8, each said low pass filter further comprising a power factor correction module.

14. An apparatus for delivering an audio signal according to claim 8, said output acoustic transducer system comprising multiple audio speakers.

15. An apparatus for delivering an audio signal according to claim 8, said output audio signal comprising a continuous 2000 watts RMS power level.

16. An apparatus for delivering an audio signal according to claim 8, said apparatus being powered with a single supply voltage.

17. An apparatus for delivering an audio signal according to claim 8, said PWM modulator configured as enabled for output only when a said audio signal is present at its input.

18. An apparatus for delivering an audio signal according to claim 17, said PWM modulator configured as disabled for output during power fluctuations and switching events.

19. An apparatus for delivering an audio signal to an acoustic transducer system, comprising
a signal conditioner for conditioning an audio signal with a low frequency cutoff and a desired output voltage range,
a pulse width modulator connected to the output of said signal conditioner for converting said audio signal into positive and negative PWM signal components 180 degrees out of phase and having a PWM switching carrier frequency higher than the highest desired audio frequency of said audio signal, said PWM modulator configured as enabled for output only when a said audio signal is present at its input, said PWM modulator further configured as disabled for output during power fluctuations and switching events,
power amplifiers for amplifying respective said PWM signal components, said power amplifiers comprising MOSFET devices,
a negative feedback loop off the output of each said power amplifier to said signal conditioner for minimizing output distortion and maintaining said output voltage range with changing load impedance and power supply voltages, said feedback loops comprising a filter and feedback buffer circuit for removing said PWM switching carrier frequency,
a low pass filter after each said power amplifier for removing said PWM switching carrier frequency from said PWM signal components thereby converting said PWM signal components into audio signal components, and
a power audio transformer for receiving and combining said audio signal components into an output audio signal, said transformer being connected and impedance matched to said output acoustic transducer system.

20. An apparatus for delivering an audio signal to an acoustic transducer system according to claim 19, each said low pass filter further comprising a power factor correction module, said apparatus being powered with a single supply voltage.
